(19) United States
(12) Patent Application Publication
(10) Pub. No.: US 2026/0003729 A1
(43) Pub. Date: Jan. 1, 2026

(54) Packet-Based One-Time Programmable Memory

(71) Applicant: TEXAS INSTRUMENTS INCORPORATED, Dallas, TX (US)

(72) Inventor: Devanathan Varadarajan, Allen, TX (US)

(21) Appl. No.: 18/754,547

(22) Filed: Jun. 26, 2024

(51) Int. Cl. G06F 11/10; G06F 11/14

(52) U.S. Cl. CPC G06F 11/1068; G06F 11/1417

(57) ABSTRACT

A one-time programmable (OTP) memory may be coupled to an OTP memory controller. The OTP memory controller may be configured to store OTP data in a packet format within the OTP memory. Data within the OTP packets may identify respective indices, where each of those indices may correspond to a configuration register or other volatile memory location. The data may be written to the OTP memory during a manufacturing process. During a boot or a reset, the OTP memory controller, in conjunction with a boot loader, may read out data from the OTP memory and cause that data to be written to locations in volatile memory according to the respective indices. After the data has been written to volatile memory, the data may be used to affect a trim of a component, support memory repair techniques, be used as a security key, etc.

### TECHNICAL FIELD

The present disclosure relates generally to electronic systems and methods, and, in particular embodiments, to packet-based one-time programmable (OTP) memory.

### BACKGROUND

Some integrated circuits (ICs) may include one-time programmable (OTP) memory to store various types of data. Examples of data in OTP memory include security keys, analog trimming data, chip identification, memory repair codes, and the like.

In one example, a manufacturer may manufacture a chip and then test that chip using a probe, perhaps under different temperature conditions. Due to process variation, various components of the chip may have different performance parameters at the different temperature conditions, and the manufacturer may generate trimming data based on the testing results. The trimming data may be used to configure one or more components on the chip, either at boot time or later, to cause the one or more components to provide desired behavior over the different temperature conditions. The manufacturing process may further include storing the analog trimming data to the OTP memory. Other OTP data may be stored similarly.

### SUMMARY

In accordance to an embodiment, an integrated circuit (IC) includes: a one-time programmable (OTP) memory; volatile memory; a controller configured to: read a first packet from the OTP memory; determine a first location of the volatile memory, at which to write a portion of a first payload of the first packet, based on a first header in the first packet; verify integrity of the first payload according to a first fault-tolerant type; read a second packet from the OTP memory; determine a second location of the volatile memory, at which to write a portion of a second payload of the second packet, based on a second header in the second packet; and verify integrity of the second payload according to a second fault-tolerant type, where the first tolerant type is different from the second fault-tolerant type.

In accordance to an embodiment, a method includes: write a first packet to a one-time programmable (OTP) memory, the first packet including a first index, a first payload, and a first fault-tolerant signature associated with a first fault-tolerant type; and write a second packet to the OTP memory adjacent the first packet, the second packet including a second index, a second payload, and a second fault-tolerant signature associated with a second fault-tolerant type.

In accordance to an embodiment, an integrated circuit (IC) includes: a one-time programmable (OTP) memory having a plurality of memory cells, where: a first set of memory cells of the plurality of memory cells have been programmed to store a first packet, the first packet including a first index, a first payload, and a first fault-tolerant signature, the first fault-tolerant signature being associated with a first fault-tolerant type; and a second set of memory cells of the plurality of memory cells have been programmed to store a second packet, the second packet including a second index, a second payload, and a second fault-tolerant signature, the second fault-tolerant signature being associated with a second fault-tolerant type.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is an illustration of an example computing system, which may read and store OTP data as packets, according to some embodiments;

FIG. 2 is an illustration of an example data organization, according to some embodiments;

FIG. 3 is an illustration of example storage within an OTP memory, according to some embodiments;

FIG. 4 is an illustration of example method, for reading data from an OTP memory and configuring configurable components with OTP data, according to some embodiments; and

FIG. 5 is an illustration of an example method, for writing packets to an OTP memory, according to some embodiments.

Corresponding numerals and symbols in different figures generally refer to corresponding parts unless otherwise indicated. The figures are drawn to clearly illustrate the relevant aspects of the preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates the various specific details to provide an in-depth understanding of several example embodiments according to the description. The embodiments may be obtained without one or more of the specific details, or with other methods, components, materials and the like. In other cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Some embodiments relate to OTP memory in computer systems.

Some embodiments relate to systems and methods for data compaction and decompaction using OTP.

It may be possible to write some data to the OTP memory in a single write operation. Such data may be referred to as single-insertion data. However, other data may employ multiple write operations to be complete. For instance, some data may be written by a manufacturer and supplemented by a customer, who also may write the data to the OTP. Such data may be referred to as multiple-insertion data. In some examples, it may be desirable to use a first fault-tolerant type for multiple-insertion data and a second fault-tolerant type for single-insertion data. It may be desirable to have a one-time programmable (OTP) memory and an OTP memory controller that may be configured to support multiple fault-tolerant types as well as data compaction and de-compaction.

Various embodiments may support multiple fault-tolerant types as well as data compaction and de-compaction by storing OTP data as packets. For instance, the packets may include a header having an index and a payload having payload data and fault-tolerant data. The payload data may be the underlying data (e.g., trimming data, security keys, memory correction data, chip identification data, and the like), and the fault-tolerant data may be derived from the underlying data, the index, and other metadata.

Various embodiments may support multiple fault-tolerant types. In one example, a system supports both ECC (error correction codes, such as single-error-correct codes and double-error-correct codes) for word-based data and redundant entries (such as TMR (triple-modular-redundancy) and QMR (quadruple modular redundancy)) for bit-based data. In one example, word-based programming may be associated with an ECC fault-tolerant type because ECC data may not be configured for reprogramming. Continuing with the example, bit-based programming may be associated with a TMR fault-tolerant type to support multiple write operations.

The index of a packet may refer to a word in a data organization. A data organization in this example may have a multitude of entries (words), each of the entries being associated with a particular configurable component and a particular data use. For instance, a particular entry may be associated with trimming data for a ring oscillator. Another entry may be associated with memory repair for a particular memory bank. Yet another entry may be associated with a security key for firmware that is stored to nonvolatile memory. Each of these different uses may be associated with a different word in the data organization. Thus, an example packet may include an index, where that index refers to a particular entry in the data organization. A configuration controller, during boot time or some other time, may determine to write payload data from the packet to a particular configurable component based upon the index.

Furthermore, the OTP data may be stored as a sparse matrix, where some data may be omitted to save space in the OTP memory. For instance, where testing may reveal that default values may be used for programming a particular configurable component, then the OTP memory and OTP memory controller may omit storing packets having indices associated with that configurable component.

Continuing with an example, an entity may store a first packet to the OTP memory by instructing the OTP memory controller to write particular payload data associated with an index. In this example, the payload data is single-insertion data and can be written using word-based programming and an ECC fault-tolerant type. The OTP memory controller receives the instruction and writes the packet, including the index as a header, the underlying data, the ECC protection data, and any metadata. Examples of metadata may include an indication of the fault-tolerant type.

Either the same entity or a different entity may store a second packet to the OTP memory, where that second packet is directed toward multiple-insertion data and a different index. For instance, the multiple-insertion data may be associated with a different fault-tolerant type, such as TMR. The OTP memory controller receives an instruction from that entity and writes a packet to the OTP memory. The packet includes the index as a header, the underlying data, the TMR protection data, and any metadata. The OTP memory controller may write the first packet and the second packet in adjacent rows within the OTP memory.

The example may include further packets being written into sequentially adjacent rows of the OTP memory until all OTP data has been written. Depending on results of testing, OTP data may be written for some indices and not written for other indices, and the total amount of OTP data written to a particular integrated circuit (IC) may vary from IC instance to IC instance based on the testing. The OTP memory may be designed to be large enough to accommodate an expected amount of OTP data and, thus, may even include some un-written rows in instances in which the amount of OTP data is less than the total number of available rows in the OTP memory.

Examples of entities that may cause the OTP memory controller to write to the OTP memory may include a manufacturer, a downstream customer, or other appropriate entity. A manufacturing process may include testing and one or more write operations to store OTP data to the OTP memory. As noted above, the OTP data may be stored as packets, while some of the data may be associated with a first fault-tolerant type, and other of the data may be associated with a second fault-tolerant type. During boot, a boot controller may cause the OTP memory controller to read out the underlying data and provide that underlying data to be usable by a configuration controller, where the index of each packet associates a particular configurable component to the underlying data. The configuration controller may further write the underlying data to associated configurable components as part of the boot process. The OTP memory controller may be configured both to write OTP data in the form of packets and to read out the underlying data from the packets, including performing any appropriate verification according to fault-tolerant type.

Various embodiments may include potential advantages. For instance, various embodiments may facilitate data compaction by the use of headers having indices. The indices may associate the underlying data in a particular packet with a particular configurable component and a particular use at that component. An entity may then write a packet for a piece of data that is desired, using its appropriate index, and may omit to write packet for a piece of data that is undesired or unneeded. The indices of the packets may be used during boot time or other appropriate time to identify respective components to be configured with the underlying data. In other words, the data compaction, or use of a sparse matrix, may allow for the use of a smaller OTP memory since the OTP memory would not be expected to store data for every possible index.

Yet another potential advantage includes support for multiple fault-tolerant types. The packet format may allow for differently sized packets, where differently sized packets may result from using multiple fault-tolerant types. In one example, an ECC fault-tolerant type may be expected to use a single row for a packet in the OTP memory, whereas a TMR fault-tolerant type may be expected to use multiple rows for a packet in the OTP memory. The packet format may allow for underlying data associated with a particular index to be written to the OTP memory and read out of the OTP memory as a single packet, regardless of the size of the packet. Therefore, a single OTP memory may be configured for use by one or more entities that may write single-insertion data and multiple-insertion data.

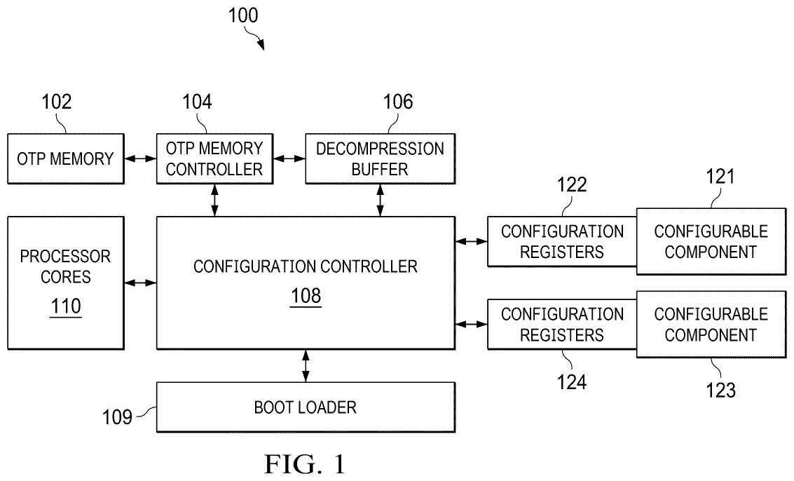

FIG. 1 is an illustration of an example computing system 100, which may read and store OTP data as packets, according to some embodiments.

Computing system 100 includes processor cores 110. Processor cores 110 may include any appropriate number and type of processor core. For instance, processor cores 110 may include general-purpose processor cores, digital signal processor (DSP) cores, reduced instruction set (RISC) processor cores, custom processors, or the like. Some embodiments may not include any processor core 110.

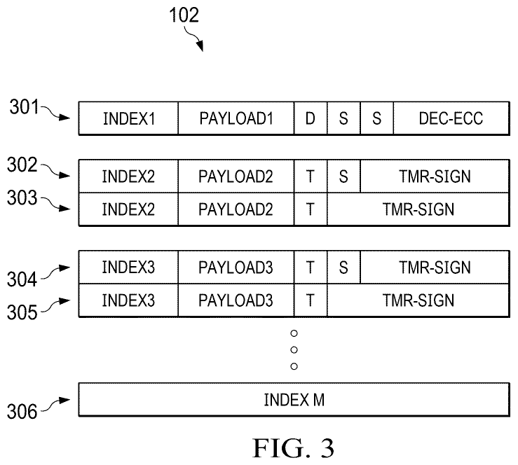

OTP memory 102 may include a multitude of individual memory cells, which are arranged in an array as rows (words) and columns. OTP memory 102 may include memory cells according to any appropriate OTP technology, such as electrical FuseROM, one-time programmable ROM (OTP ROM), electrically programmable ROM (EPROM), or electrically erasable programmable ROM (EEPROM). OTP memory 102 may store OTP data as packets, such as shown in more detail with respect to FIG. 3.

OTP memory controller 104 may include hardware, firmware, or software logic which is configured to write to OTP memory 102 and read from OTP memory 102. For instance, OTP memory controller 104 may include functionality to receive a write instruction from an entity, such as over a Joint Test Action Group (JTAG) interface or other appropriate interface. The write instruction may include index data and the underlying data. In response, the OTP memory controller 104 may write a packet to OTP memory 102.

During a boot sequence, boot loader 109 may send a read instruction to the OTP memory controller 104. In response, the OTP memory controller 104 may read out the OTP data from OTP memory 102 so that the OTP data may be used to configure one or more components, such as configurable components 121 and 123 as well as processor cores 110. Boot loader 109 may include hardware, firmware, and/or software logic to boot system 100, such as at power-on or restart.

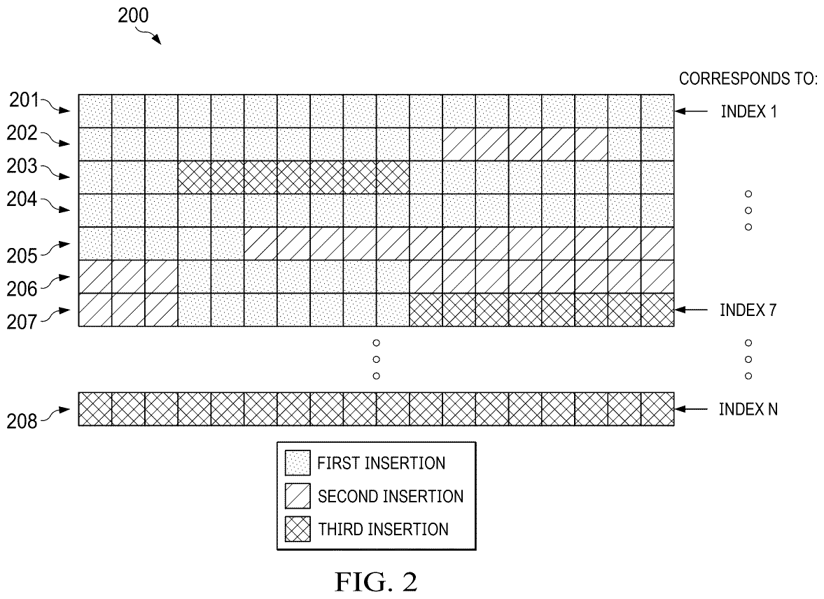

In one example, OTP memory controller 104 reads the contents of a packet from OTP memory 102, performs a verify operation according to an appropriate fault-tolerant type, and moves at least some of the contents of the packet to the decompression buffer 106. For instance, the OTP memory controller 104 may perform a read operation on the entire OTP memory 102 and then move the underlying data into appropriate positions within the decompression buffer 106. The appropriate positions within the decompression buffer 106 may be determined by the respective indices of the packets, thereby reconstituting a data organization, such as the example data organization described in more detail with respect to FIG. 2. Decompression buffer 106 may be implemented in any appropriate manner, such as by static random-access memory (SRAM) or other appropriate volatile memory.

Decompression buffer 106 may be implemented as a reorder buffer in some embodiments. Configuration controller 108 may then read the data from the decompression buffer 106 and write the data to appropriate configuration registers, such as configuration registers 122 and 124. A position of data within the data organization may correspond to a particular configurable component and/or configuration register. A given configurable component 121, 123 may be configured for operation by virtue of the data being written to its configuration registers 122, 124.

Some embodiments may include OTP memory controller 104 reading the data from OTP memory 102 and transferring that data directly to configuration controller 108 without writing the data to decompression buffer 106. Some such embodiments may be implemented without decompression buffer 106. In some such an example, the OTP memory controller 104 may transfer the data in a manner that allows the configuration controller 108 to associate a particular piece of data with a particular configuration register 122, 124. For instance, the OTP memory controller 104 may transfer the data as well as its associated index to the configuration controller 108. The configuration controller 108 may then use the indices to map against entries in a lookup table (not shown) to determine which configuration registers should receive which data. In another example, the OTP memory controller 104 may transfer the data in a particular order, where the order of transmission and potentially symbols in between data, may act as a proxy for indices. However, the scope of implementations is not limited to any particular technique to move data from OTP memory 102 to the configuration registers 122, 124.

System 100 is shown including two configurable components 121, 123. The scope of implementations is not limited to any particular number of configurable components, and the principles described herein may be adapted for use with any appropriate number of configurable components (including 0, 1, 2, 3, 10, or more). Examples of configurable components include analog components (e.g., ring oscillators, analog-to-digital converters, digital to analog converters, resistor ladders, transducers), digital components such as embedded memories, hardware logic, and the like. In the case of analog components, the data written to configuration registers may include trimming data or repair data to change an operation of such components. In the case of digital components, the data written to configuration registers may include pointers to spare memory rows or to malfunctioning rows, security keys, and the like. Furthermore, processor cores 110 may be configurable components themselves, as the boot process may include writing a processor identification (ID) or other information to configuration registers (not shown) of the processor cores 110.

Moreover, while the configuration controller 108 and the boot loader 109 are shown as separate components, in some implementations the configuration controller 108 may be a portion of logic of the boot loader 109 or may be a software or firmware routine of the boot loader 109. In fact, any of the components that may be used during a boot operation or reset, such as the OTP memory controller 104, decompression buffer 106, and configuration controller 108 may be included within the logic or software/firmware functionality of the boot loader 109.

Also, the collective size of the configuration registers (including configuration registers 122 and 124 and perhaps others) may be the same as or different from a size of the OTP memory 102.

System 100 may be built on one or more ICs. For instance, the various components 102-110 and 121-124 may be built on one or more semiconductor dies. The semiconductor dies may be packaged into one or more semiconductor packages. In some instances, system 100 may be built as a system on-chip (SoC) or on multiple chips. The scope of implementations is not limited to any chip architecture.

In some embodiments, configuration controller 108 may be implemented by a generic or custom processor or controller, e.g., capable of executing instructions from a memory. In some embodiments, confirmation controller may be implemented with a field programmable gate array (FPGA). In some embodiments, confirmation controller 108 is implemented with a state machine. In some embodiments, confirmation controller 108 is not programmable.

FIG. 2 is an illustration of an example data organization 200, according to some embodiments. Data organization 200 represents a set of all possible cases of OTP data that may be written to OTP memory 102. For instance, row 201 may be associated with index 1, which may be associated with a particular configuration register within a system, such as within system 100. Each of the rows 201-208 is associated with a respective index and a respective configuration register or set of configuration registers. Configuration controller 108 may be preprogrammed to associate OTP data with its respective row 201-208 in the data organization 200. For instance, the configuration controller 108 may include a lookup table or other appropriate data structure configured to provide a logical association between a given piece of OTP data and a given configuration register or set of configuration registers. In one example, index information may be used as a key in a lookup table by configuration controller 108. In another example, OTP memory controller may construct a table within decompression buffer 106, and configuration controller 108 may be configured to associate entries from the decompression buffer 106 to a particular row 201-208 of the data organization 200.

As noted above, some configurable components may be revealed by testing to be well served by default values rather than corrective values in OTP data. Therefore, the OTP memory 102 may store data for some indices and omit storing data for other indices, thereby implementing a sparse matrix. Additionally, a manufacturer may use a same OTP memory and a same data structure across multiple models of chips within a chip family. Some of those chip models may have overlapping indices, whereas some of those chip models may have subsets of indices that are specific to only a particular model within the family. For example, in some embodiments, an instance of a chip (e.g., system 100) may only be associated with certain ones of the indices 201-208 in some examples, and another chip instance of a different chip model within the same family may be associated with different ones of the indices 201-208, though there may be some overlap. FIG. 2 illustrates N quantity of available indices, where N is a positive integer and may be appropriately scaled for a given computing system.

The entirety of row 201 corresponds to a first insertion only. In this example, a row of the data organization 200 having only a single insertion may be amenable to an ECC fault-tolerant type. The same is true for row 204. Therefore, packets corresponding to rows 201 and 204 may be stored in OTP memory 102 having different indices but perhaps having a same fault-tolerant type.

By contrast, row 202 has data associated with the first insertion as well as the second insertion. In other words, row 202 represents multiple-insertion data. Similarly, row 203 has data associated with the first insertion and the third insertion. Row 205 has data associated with the first insertion and the second insertion, as does row 206. Row 207 has data associated with the first insertion, the second insertion and the third insertion. In this example, multiple-insertion data may be amenable to a TMR fault-tolerant type. Packets corresponding to rows 202, 203 and 205-207 may be stored in OTP memory 102 having different indices but perhaps having a same fault-tolerant type. Row 208 has data associated with only the third insertion and, being single-insertion data, may be amenable to an ECC fault-tolerant type.

An example of single-insertion data may include data that may be stored by a single entity and does not change based on voltage, temperature, or other operating condition. For existence, a security key may be stored by an entity, such as a manufacturer or authorized customer. Such data may represent the entirety of the data associated with a row (e.g., row 201) in data organization 200.

An example of multiple-insertion data may include trimming data for an analog device, where that trimming data may be expected to be different at certain operating conditions. In one example, testing may be performed at a first operating condition, and an entity may instruct OTP memory controller 104 to store partial trimming data based on that testing to a packet in OTP memory 102. Testing may then be performed at a later time at a second operating condition. The entity (or a different entity) may instruct OTP memory controller 104 to store further partial trimming data based on that testing to the same packet in OTP memory 102. Together, each partial trimming data may represent the entirety of the data associated with a row (e.g., row 202) in data organization 200.

In a further example, a first entity may store partial data to a packet in OTP memory 102, and another entity (e.g., downstream customer) may receive that chip and store further partial data to the same packet in OTP memory 102. The scope of implementations may be adapted to include any appropriate quantity of insertions within a given row of data organization 200.

FIG. 3 is an illustration of example storage within OTP memory 102, according to some embodiments. The example of FIG. 3 illustrates OTP data that may correspond to rows 201-203 of the example of FIG. 2.

OTP memory 102 may be configured physically to include an appropriate quantity of memory cells arranged in rows and columns. Example rows 301-306 are shown in FIG. 3. The quantity of rows (R) may be any appropriate positive integer and may be different from the quantity N of the example of FIG. 2. In one example use case, a designer of system 100 may determine a quantity of rows that may be reasonably expected to be used within OTP memory 102 and may size OTP memory 102 accordingly.

OTP memory 102 stores data in row 301 as a packet, and that packet corresponds to index 1, which further corresponds to index 1 and row 201 of example data organization 200. Rows 302-303 correspond to index 2, which further corresponds to index 2 and row 202. Similarly, rows 304-305 correspond to index 3, which further corresponds to index 3 and row 203. For ease of illustration, FIG. 3 only illustrates rows 301-305 as being written, and it is understood that other rows not illustrated up to a total of R rows may be written as appropriate.

In this example, indices 1-3 include data to be written in OTP memory 102. However, in another example, not all or any of indices 1-3 may be written in OTP memory 102. Which indices are written into rows of OTP memory 102 may depend on chip model, results of testing, and the like. For instance, in one example, data may be written for index 1 and index 3 but not for index 2. In another example, the particular chip model may not include any indices until a higher number (e.g., 101). In some embodiments, the indices may be written and/or stored in order (e.g., index 1, index 2, index 3, etc.), e.g., with some of the indices being omitted. In some embodiments, the indices may be written and/or stored out of order (e.g., index 3, index 1, index 4, etc.), e.g., with some of the indices being omitted.

OTP memory controller 104 may write data to rows beginning at row 301 and continuing as appropriate through higher numbered rows and even through a total of R rows if needed. Furthermore, OTP memory controller 104 may write, regardless of index, beginning at row 301 and increasing in row number through the rows so that the rows as written are adjacent. The total number of rows written may be fewer than R, in which case rows of a higher number may not be written so that they include all zeros or all ones. In one example, the total quantity of rows to be written may be 50, so the OTP memory controller begins at row 301 and writes to a total of 50 adjacent rows and leaves remaining rows through row 306 unwritten. In some such examples, OTP memory controller 104 may be configured to end a read operation of OTP memory 102 upon encountering a row of all zeros or all ones.

Row 301 stores a first packet. The packet corresponds to index 1. From left to right in the row 301 data is stored as: an identifier of index 1, the underlying data as payload 1, an identifier of a fault-tolerant type as “D”, spare bits “S”, and ECC data. In this example, the ECC data protects the index data, the payload data, and the D bit. Further in this example, the ECC data may include a hash of the protected data. An example of the payload data may include a security key, trimming data, or the like.

The structure of the packet of row 301 includes the index 1 being a header of the packet, which is followed by a payload that includes payload 1, the fault-tolerant bit, the spare bits, and the ECC data. In other words, payload 1, which is the underlying data, is not the entire payload.

Rows 302-303 store a second packet, which corresponds to index 2. As noted in the discussion of FIG. 2, index 2 is associated with multiple-insertion data and, in this example, is protected using a TMR fault-tolerant type. For instance, a TMR fault-tolerant type might simply include three copies of the underlying data. Row 302 includes a header having an identifier of index 2. Row 302 stores the underlying data as payload 2. The bit “T” identifies the fault-tolerant type, and there is a spare bit “S”. The remainder of row 302 and the entirety of row 303 store TMR fault-tolerant data, which protects the index identifier, the underlying data of payload 2, and the T bit. Specifically, row 303 is illustrated as including a second copy of the index 2 identifier, payload 2, and the T bit. That is two out of three of the copies according to this example TMR fault-tolerant type. The third copy is included in the TMR-SIGN data spanning rows 302 and 303.

In some embodiments, the fault-tolerant type may include a single bit. The fault-tolerant bit having a first value (e.g., 0), is indicative of a “D” value (e.g., ECC). The fault-tolerant bit having a second value (e.g., 1), is indicative of a “T” value (e.g., TMR). In some embodiments, the fault-tolerant type field may include more than 1 bit and may support more than 2 fault-tolerant types.

In the packet of rows 302-303, the index identifier in row 302 is the header; the payload includes everything else in rows 302-303.

Rows 304 and 305 store a third packet, which corresponds to index 3 and payload 3. The third packet is stored using a same packet format as the second packet of rows 302-303. Other rows subsequent to row 305 may include store additional packets as appropriate.

OTP memory controller 104 may be configured to identify different packets during a read operation by parsing the index identifier of a given row. For instance, the memory controller 104 may be configured to treat the contents of adjacent rows as a single packet when those adjacent rows have the same index identifying data. Similarly, the memory controller 104 may be configured to treat the contents of rows having different index identifying data as different packets.

Moreover, OTP memory controller 104 may be configured to identify a fault-tolerant type by parsing information in a particular packet, such as the D and T bits illustrated in FIG. 3. Thus, in one example, the OTP memory controller may read the data from row 301, parse the data in the row to identify the D bit, and perform a verification operation for an ECC fault-tolerant type based on the D bit. Assuming that the verification operation indicates uncorrupted data, then the OTP memory controller 104 may treat the index 1 data and the payload 1 data as usable data.

Similarly, OTP memory controller 104 may read the data from rows 302-303, parse the T bit of row 302 to identify a TMR fault-tolerant type, and perform a verification operation for the TMR fault-tolerant type in response to the T bit. Assuming that the verification operation indicates uncorrupted data, then the OTP memory controller 104 may treat a single copy of the index 2 data and the payload 2 data as useful data. The OTP memory controller may be configured to read the third packet of rows 304-305 in a similar manner.

As can be inferred, in some embodiments, a particular index may be associated with different fault-tolerant types, depending on the value of the fault-tolerant field. For example, a first device may have index 1 associated with a D value, and a second device may have index 1 associated with a T value. As such, OTP memory 102 of the first device may use 1 row for storing information associated with index 1, and OTP memory 102 of the second device may use 2 rows for storing information associated with index 1.

In another example, the OTP memory controller 104 may be preprogrammed with a lookup table or other data structure to associate a given index with a given fault-tolerant type. In some such examples, the different packets may omit storing bits to indicate a fault-tolerant type, as the OTP memory controller 104 may be configured to identify the fault-tolerant type from the index identifying data.

The OTP memory controller 104 may be configured to perform further operations on the useful data. For instance, the OTP memory controller 104 may populate rows of the decompression buffer 106 with the underlying data from the different payloads in an order corresponding to the index data associated with each payload. In another example, OTP memory controller 104 may populate rows of the decompression buffer 106 with both underlying data and index data. In yet another example, in which the decompression buffer 106 is not used or is omitted, the memory controller 104 be configured to provide the underlying data and associated index data to the configuration controller 108. In any event, the configuration controller 108 is configured to acquire the underlying data from the payloads, and the corresponding index data may be explicit or implied to allow the configuration controller 108 to load the underlying data from the payloads into appropriate configuration registers. In some embodiments, the configuration registers that do not have payload data loaded onto them (e.g., because the associated index was not written in OTP memory 102), keep default values (which may be hardwired).

In the example above, the packets are shown as being physically adjacent in the rows of the OTP memory 102. In another example, the OTP memory 102 may be subject to a virtual addressing scheme and may be split into two or more physical memory portions. In such an example, the OTP memory controller 104 may include a map that translates logical addresses into physical addresses of the OTP memory 102. In such an example, write operations to the OTP memory 102 may be made toward virtual addresses, which are then translated to physical addresses. Those physical addresses may or may not be physically adjacent but may still be logically adjacent, such as by virtue of adjacent numbering of virtual addresses. Adjacent numbering of virtual addresses may be associated with an order of reading in a read operation. As an example, the first packet of row 301 may be physically adjacent, logically adjacent, or both to the second packet of rows 302-303. In some embodiments, whether the first packet is physically adjacent to the second packet, they may be read with two read operations one after the other. The scope of implementations may be adapted to use any addressing scheme.

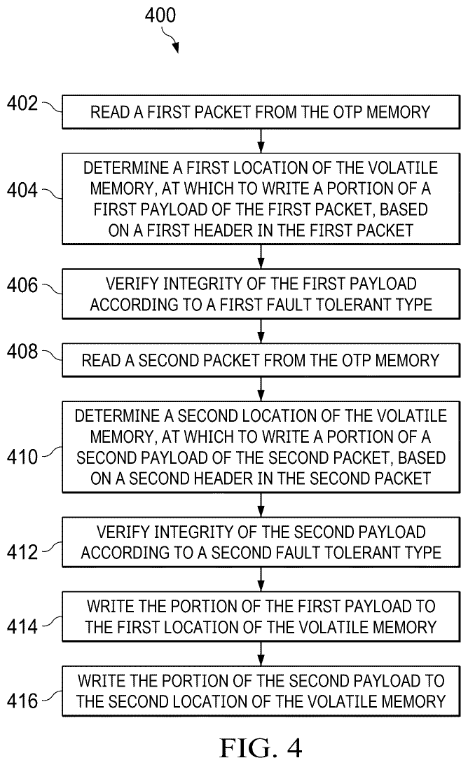

FIG. 4 is an illustration of example method 400, for reading data from an OTP memory and configuring configurable components with OTP data, according to some embodiments. Method 400 may be performed by components of example system 100, such as OTP memory controller 104 and configuration controller 108. For instance, the OTP memory controller 104 and configuration controller 108 may include hardware logic or may execute firmware or software to provide the actions described.

Action 402 includes reading a first packet from the OTP memory. Examples of packets are discussed above with respect to FIG. 3. In one example, OTP memory controller 104 may read out the entirety of stored data from OTP memory 102, ending the read operation upon detecting a row having all ones or all zeros. Continuing with the example, the OTP memory controller 104 may then parse the index information in the rows to identify individual packets. However, the scope of implementations may include any appropriate technique to identify packets from reading out data.

Action 404 includes determining a first location of a volatile memory at which to write a portion of a first payload of the first packet. For instance, action 404 may include determining the first location of the volatile memory based on a first header in the first packet.

In one example, the OTP memory controller 104 may parse the first packet to analyze the index identifier data and then determine where, in volatile memory, to write at least a portion of the first payload. For instance, the OTP memory controller 104 may write at least a portion of the first payload to a buffer, such as decompression buffer 106, in a particular place in that buffer in response to the index identifying data. In one example, the decompression buffer 106 may include a reorder buffer so that the OTP memory controller 104 may write the first packet into the reorder buffer in a different order than the first packet would be read out of the reorder buffer. However, the decompression buffer 106 is not limited to any particular structure, whether as a reorder buffer or otherwise.

Continuing with the example, the configuration controller 108 may read the contents out of the decompression buffer 106 and then determine to write the underlying data from the first packet into a corresponding configuration register. For instance, the index and configuration register association may be implicit in the placement of the data within the buffer or may be explicit by inclusion of index information in the buffer. In any event, the configuration controller 108 may be configured to write the underlying data from the first packet into an appropriate configuration register and in accordance with the index identifying data in the first packet.

In some embodiments, the configuration controller 108 may receive index identifying data and the underlying data from the OTP memory controller 104. The configuration controller 108 may then parse the index identifying data to determine the index and then write the underlying data from the first packet to a corresponding configuration register based on the index identifying data.

Action 406 includes verifying integrity of the first payload according to a first fault-tolerant type. Action 406 may be performed before action 404 in some examples. In one example, the OTP memory controller 104 determines a fault-tolerant type, either from a fault-tolerant type bit (e.g., a D or T bit) or based on the index identifying data. The OTP memory controller 104 may then perform a process, in accordance with the determined fault-tolerant type, to verify the integrity of the data in the packet. For instance, in the case of ECC encoding, the OTP memory controller 104 may be configured to apply a hashing algorithm to data in the packet and then compare the result of the hashing algorithm to the ECC data of the packet. In the case of TMR encoding, the OTP memory controller 104 may be configured to apply a voting algorithm (e.g., two out of three voting) to verify integrity. Of course, the scope of implementations is not limited to any particular fault-tolerant type or associated integrity verification process.

Actions 408-412 are performed on a second packet and are similar to actions 402-406. For instance, actions 402-406 may be applied to the packet of row 301 of FIG. 3, and actions 408-412 may be applied to the packet of rows 302-303 of FIG. 3. Of note is that the second packet uses a different fault-tolerant type than does the first packet. Nevertheless, both packets are accommodated in OTP memory 102, and both packets may be written by and read by OTP memory controller 104, e.g., by virtue of the packet format of FIG. 3, which may use index identifiers to identify individual packets within OTP memory 102 and may use index identifiers or fault-tolerant type bits to identify a fault-tolerant type.

At action 414, the portion of the first payload is written to the first location of the volatile memory. Action 414 may include the OTP memory controller 104 writing contents of the first packet to the decompression buffer 106. In this example, action 414 may also include the configuration controller 108 reading data from the decompression buffer 106 and writing the data to an appropriate configuration register that corresponds to the index identifying data of the first packet. Action 414 may include, in some examples, the OTP memory controller 104 writing contents of the first packet to the configuration controller 108, where the configuration controller 108 writes the data to an appropriate configuration register that corresponds to the index identifying data of the first packet.

The second packet, as noted above, corresponds to a different index than does the first packet. Thus, action 416 may be performed similarly to action 414, with the result being that data from the second packet is written to an appropriate configuration register according to the index of the second packet. The data from the first packet and the data from the second packet are, therefore, written to different configuration registers.

Method 400 may include other actions not shown. For instance, a particular configurable component may be associated with a configuration register. As part of the boot process, that particular configurable component may read from its configuration register and apply the data from its configuration register to its operation. For instance, the configurable component may apply the data as trimming data, security key data, memory repair data, component ID data, or the like as appropriate.

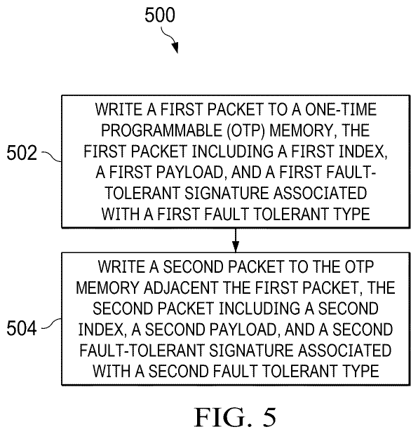

FIG. 5 is an illustration of an example method 500, for writing packets to an OTP memory, according to some embodiments. For instance, an OTP memory controller, such as OTP memory controller 104, may write a multitude of packets to an OTP memory, such as OTP memory 102. Example method 500 may be performed before deployment of a computing system, such as computing system 100, such as during a manufacturing process that may span more than one entity.

Action 502 includes writing a first packet to the OTP memory. An example of the first packet may include the packet in row 301 of FIG. 3. The packet may include a first index, such as in a header of the packet. The packet may also include a first payload and a first fault-tolerant signature associated with the first fault-tolerant type. The packet of row 301 is an example of a single-insertion packet, and it may be associated with a word-based fault-tolerant type, such as an ECC type. The fault-tolerant signature may include a hash of at least some of the data in the packet.

In another example, the first packet may include the packet of rows 302-303 of FIG. 3. Such packet may include an index, a payload, and a fault-tolerant signature associated with its particular fault-tolerant type. The example packet of rows 302-303 is a multiple-insertion packet, which may be associated with a bit-based fault-tolerant type, such as a redundancy-based type (e.g., TMR, QMR). The fault-tolerant signature may include one or more additional copies of at least some of the data in the packet.

Action 504 includes writing a second packet to the OTP memory adjacent to the first packet. The first packet and the second packet may be physically adjacent in the OTP memory. The first packet and a second packet may be logically adjacent in the OTP memory and may either be physically adjacent or not physically adjacent in the OTP memory. In any event, the second packet is a different packet from the first packet, having a different index, different payload, a different fault-tolerant signature, and a different fault-tolerant type.

Method 500 may include further actions, such as writing further packets to the OTP memory. In one example, the second packet is a multiple-insertion packet, and action 504 may include multiple non-consecutive writing operations. For instance, a third packet may be written to the OTP memory after a first portion of the second packet is written and before a second portion of the second packet is written. Any given packet may be single-insertion or multiple-insertion, and the OTP memory may be under control of an OTP memory controller that is adapted for writing packets of different lengths and different fault-tolerant types as well as reading out data that is in packets of different links and different fault-tolerant types.

Furthermore, method 500 may include writing data identifying fault-tolerant types to the respective packets, such as is illustrated in FIG. 3. In another embodiment, method 500 may omit writing data identifying fault-tolerant types, as such data may be implied from index identifying data.

Example embodiments of the present disclosure are summarized here. Other embodiments can also be understood from the entirety of the specification and the claims filed herein.

Example 1. An integrated circuit (IC) including: a one-time programmable (OTP) memory; volatile memory; a controller configured to: read a first packet from the OTP memory; determine a first location of the volatile memory, at which to write a portion of a first payload of the first packet, based on a first header in the first packet; verify integrity of the first payload according to a first fault-tolerant type; read a second packet from the OTP memory; determine a second location of the volatile memory, at which to write a portion of a second payload of the second packet, based on a second header in the second packet; and verify integrity of the second payload according to a second fault-tolerant type, where the first tolerant type is different from the second fault-tolerant type.

Example 2. The IC of example 1, where the controller is further configured to: write the portion of the first payload to the first location of the volatile memory; and write the portion of the second payload to the second location of the volatile memory.

Example 3. The IC of one of examples 1 or 2, where the volatile memory includes a first register associated with a first component of the IC, and a second register associated with a second component of the IC, where the first location of the volatile memory includes a portion of the first register, and where the second location of the volatile memory includes a portion of the second register.

Example 4. The IC of one of examples 1 to 3, where the controller is configured to write the portion of the first payload to the first location of the volatile memory responsive to verifying integrity of the first payload.

Example 5. The IC of one of examples 1 to 4, where the volatile memory is a first volatile memory, the IC further including: a second volatile memory; and a boot loader configured to, during a boot sequence of the IC and after the first volatile memory has been written with the portions of the first and second payloads, copy content from the first volatile memory to the second volatile memory.

Example 6. The IC of one of examples 1 to 5, where the controller includes the boot loader.

Example 7. The IC of one of examples 1 to 6, where the second volatile memory includes a plurality of registers associated with a plurality of components of the IC, where copying content from the first volatile memory to the second volatile memory includes writing the portion of the first payload to a first register of the plurality of registers and writing the portion of the second payload to a second register of the plurality of registers.

Example 8. The IC of one of examples 1 to 7, where the controller is configured to write the portions of the first and second payloads to the first volatile memory in a different order from the order in which the boot loader copies the portions of the first and second payloads to the first and second registers.

Example 9. The IC of one of examples 1 to 8, where the first volatile memory has a same size as the second volatile memory.

Example 10. The IC of one of examples 1 to 9, where the controller is further configured to: write the portion of the first payload to a first location of the OTP memory; and write the portion of the second payload to a second location of the OTP memory.

Example 11. The IC of one of examples 1 to 10, where the second packet is logically adjacent to the first packet in the OTP memory.

Example 12. The IC of one of examples 1 to 11, where the second packet is physically adjacent to the first packet in the OTP memory.

Example 13. The IC of one of examples 1 to 12, where the controller is further configured to: detect an empty portion of the OTP memory; and end a read operation of the OTP memory in response to detecting the empty portion.

Example 14. The IC of one of examples 1 to 13, where the controller is configured to detect the empty portion by detecting a sequence of bits having a same value, where the sequence of bits has a predetermined length.

Example 15. The IC of one of examples 1 to 14, where to verify integrity of the first payload, the controller is configured to: parse first data in the first packet, the first data identifying the first fault-tolerant type; and perform a verification operation on the first packet according to the first fault-tolerant type in response to parsing the first data.

Example 16. The IC of one of examples 1 to 15, where to verify integrity of the first payload, the controller is configured to: use the first fault-tolerant type or the second fault-tolerant type in response to parsing first data in the first packet, the first data identifying either the first fault-tolerant type or the second fault-tolerant type.

Example 17. The IC of one of examples 1 to 16, where the controller includes logic identifying the first fault-tolerant type for the first packet and identifying the second fault-tolerant type for the second packet.

Example 18. The IC of one of examples 1 to 17, where the first packet and the second packet are adjacent according to a read operation order.

Example 19. The IC of one of examples 1 to 18, where each memory cell of the OTP memory includes a plurality of transistors.

Example 20. The IC of one of examples 1 to 19, where each memory cell of the OTP memory includes an e-fuse.

Example 21. A method including: write a first packet to a one-time programmable (OTP) memory, the first packet including a first index, a first payload, and a first fault-tolerant signature associated with a first fault-tolerant type; and write a second packet to the OTP memory adjacent the first packet, the second packet including a second index, a second payload, and a second fault-tolerant signature associated with a second fault-tolerant type.

Example 22. The method of example 21, where the first index corresponds to a first location in a volatile memory, and where the second index corresponds to a second location in the volatile memory.

Example 23. The method of one of examples 21 or 22, where the first payload includes trimming data associated with a first component of an integrated circuit (IC), and where the second payload includes trimming data associated with a second component of the IC.

Example 24. The method of one of examples 21 to 23, where the first payload includes trimming data associated with a first component of an integrated circuit (IC), and where the second payload includes a cryptographic key.

Example 25. The method of one of examples 21 to 24, where the first payload includes trimming data associated with a first component of an integrated circuit (IC), and where the second payload includes memory repair data of a second component of the IC.

Example 26. The method of one of examples 21 to 25, where the first fault-tolerant signature includes data generated based on the first payload according to the first fault-tolerant type.

Example 27. The method of one of examples 21 to 26, where writing the second packet includes: writing a first portion of the second packet to a first set of memory cells of the OTP memory; writing a third packet to the OTP memory; and subsequent to writing the third packet, writing a second portion of the second packet to a second set of memory cells of the OTP memory.

Example 28. The method of one of examples 21 to 27, where writing the first packet includes: writing data to the first packet, the data indicating the first fault-tolerant type.

Example 29. The method of one of examples 21 to 28, where writing the first packet includes writing to a first row of memory cells of the OTP memory, and where writing the second packet includes writing to a second row of memory cells of the OTP memory, where the first row and the second row are physically adjacent in the OTP memory.

Example 30. An integrated circuit (IC) including: a one-time programmable (OTP) memory having a plurality of memory cells, where: a first set of memory cells of the plurality of memory cells have been programmed to store a first packet, the first packet including a first index, a first payload, and a first fault-tolerant signature, the first fault-tolerant signature being associated with a first fault-tolerant type; and a second set of memory cells of the plurality of memory cells have been programmed to store a second packet, the second packet including a second index, a second payload, and a second fault-tolerant signature, the second fault-tolerant signature being associated with a second fault-tolerant type.

Example 31. The IC of example 30, where each of the plurality of memory cells includes a plurality of transistors.

Example 32. The IC of one of examples 30 or 31, where each of the plurality of memory cells include an e-fuse.

Example 33. The IC of one of examples 30 to 32, where the first payload includes one or more bits indicative of the first fault-tolerant type.

Example 34. The IC of one of examples 30 to 33, where the second payload includes one or more bits indicative of the second fault-tolerant type.

Example 35. The IC of one of examples 30 to 34, where the first fault-tolerant type is an error correction code (ECC) type, and where the second fault-tolerant type is a redundancy type.

Example 36. The IC of one of examples 30 to 35, where the first set of memory cells is logically adjacent to the second set of memory cells.

Example 37. The IC of one of examples 30 to 36, where the first set of memory cells is physically adjacent to the second set of memory cells.

Example 38. The IC of one of examples 30 to 37, where the first set of memory cells is arranged in a first row of the OTP memory, and where the second set of memory cells is arranged in a second row of the OTP memory.

Example 39. The IC of one of examples 30 to 38, where the first payload includes one or more bits that correspond to a first component of the IC, and where the second index includes one or more bits that correspond to a second component of the IC.

Example 40. The IC of one of examples 30 to 39, where the first payload includes trimming data for a first component of the IC, and where the second payload includes trimming data for a second component of the IC.

Example 41. The IC of one of examples 30 to 40, where the first payload includes a chip identification for the IC.

Example 42. The IC of one of examples 30 to 41, further including volatile memory, where the first index corresponds to a first volatile memory location on the IC, and where the second index corresponds to a second volatile memory location on the IC.

Example 43. The IC of one of examples 30 to 42, where the first set of memory cells is larger in quantity than the second set of memory cells.

Example 44. The IC of one of examples 30 to 43, where the first set of memory cells is twice as large in quantity as is the second set of memory cells.

The term “semiconductor package” is used herein. A semiconductor package has at least one semiconductor die electrically coupled to terminals and has a package body that protects and covers the semiconductor die. In some arrangements, multiple semiconductor dies can be packaged together. Additional components such as passive components, such as capacitors, resistors, and inductors or coils, can be included in the packaged electronic device. The semiconductor die may be mounted with a package substrate that provides conductive leads. A portion of the conductive leads form the terminals for the packaged device. In wire bonded integrated circuit packages, bond wires couple conductive leads of a package substrate to bond pads on the semiconductor die. The semiconductor die can be mounted to the package substrate with a device side surface facing away from the substrate and a backside surface facing and mounted to a die pad of the package substrate. The semiconductor package can have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions form the terminals for the semiconductor package. The semiconductor package may also be referred to as a “integrated circuit package,” a “microelectronic device package,” or a “semiconductor device package.”

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present disclosure should not be limited by any of the examples described above. Rather, the scope of the disclosure should be defined in accordance with the following claims and their equivalents.

What is claimed is:

1. An integrated circuit (IC) comprising:
a one-time programmable (OTP) memory;
volatile memory;
a controller configured to:
read a first packet from the OTP memory;
determine a first location of the volatile memory, at which to write a portion of a first payload of the first packet, based on a first header in the first packet;
verify integrity of the first payload according to a first fault-tolerant type;
read a second packet from the OTP memory;
determine a second location of the volatile memory, at which to write a portion of a second payload of the second packet, based on a second header in the second packet; and
verify integrity of the second payload according to a second fault-tolerant type, wherein the first tolerant type is different from the second fault-tolerant type.

2. The IC of claim 1, wherein the controller is further configured to:
write the portion of the first payload to the first location of the volatile memory; and
write the portion of the second payload to the second location of the volatile memory.

3. The IC of claim 2, wherein the volatile memory comprises a first register associated with a first component of the IC, and a second register associated with a second component of the IC, wherein the first location of the volatile memory comprises a portion of the first register, and wherein the second location of the volatile memory comprises a portion of the second register.

4. The IC of claim 2, wherein the controller is configured to write the portion of the first payload to the first location of the volatile memory responsive to verifying integrity of the first payload.

5. The IC of claim 2, wherein the volatile memory is a first volatile memory, the IC further comprising:
a second volatile memory; and
a boot loader configured to, during a boot sequence of the IC and after the first volatile memory has been written with the portions of the first and second payloads, copy content from the first volatile memory to the second volatile memory.

6. The IC of claim 5, wherein the controller comprises the boot loader.

7. The IC of claim 5, wherein the second volatile memory comprises a plurality of registers associated with a plurality of components of the IC, wherein copying content from the first volatile memory to the second volatile memory comprises writing the portion of the first payload to a first register of the plurality of registers and writing the portion of the second payload to a second register of the plurality of registers.

8. The IC of claim 7, wherein the controller is configured to write the portions of the first and second payloads to the first volatile memory in a different order from the order in which the boot loader copies the portions of the first and second payloads to the first and second registers.

9. The IC of claim 5, wherein the first volatile memory has a same size as the second volatile memory.

10. The IC of claim 1, wherein the controller is further configured to:
write the portion of the first payload to a first location of the OTP memory; and
write the portion of the second payload to a second location of the OTP memory.

11. The IC of claim 1, wherein the second packet is logically adjacent to the first packet in the OTP memory.

12. The IC of claim 1, wherein the second packet is physically adjacent to the first packet in the OTP memory.

13. The IC of claim 1, wherein the controller is further configured to:
detect an empty portion of the OTP memory; and
end a read operation of the OTP memory in response to detecting the empty portion.

14. The IC of claim 13, wherein the controller is configured to detect the empty portion by detecting a sequence of bits having a same value, wherein the sequence of bits has a predetermined length.

15. The IC of claim 1, wherein to verify integrity of the first payload, the controller is configured to:
parse first data in the first packet, the first data identifying the first fault-tolerant type; and
perform a verification operation on the first packet according to the first fault-tolerant type in response to parsing the first data.

16. The IC of claim 1, wherein to verify integrity of the first payload, the controller is configured to:
use the first fault-tolerant type or the second fault-tolerant type in response to parsing first data in the first packet, the first data identifying either the first fault-tolerant type or the second fault-tolerant type.

17. The IC of claim 1, wherein the controller includes logic identifying the first fault-tolerant type for the first packet and identifying the second fault-tolerant type for the second packet.

18. The IC of claim 1, wherein the first packet and the second packet are adjacent according to a read operation order.

19. The IC of claim 1, wherein each memory cell of the OTP memory comprises a plurality of transistors.

20. The IC of claim 1, wherein each memory cell of the OTP memory comprises an e-fuse.
